(19) United States
(12) Patent Application Publication
(10) Pub. No.: US 2025/0070662 A1
(43) Pub. Date: Feb. 27, 2025

(54) APPARATUS AND METHODS OF FABRICATING A SWITCHED CAPACITOR CIRCUIT

(71) Applicant: Murata Manufacturing Co., Ltd., Nagaokakyo-shi (JP)

(72) Inventor: David Giuliano, Bedford, NH (US)

(21) Appl. No.: 18/945,360

(22) Filed: Nov. 12, 2024

Related U.S. Application Data
(63) Continuation of application No. PCT/US2023/066886, filed on May 11, 2023.
(60) Provisional application No. 63/364,569, filed on May 12, 2022.
(60) Provisional application No. 63/364,674, filed on May 13, 2022.

(51) Int. Cl. H02M 3/07; H03H 19/00

(52) U.S. Cl. CPC H02M 3/072; H03H 19/004

(57) ABSTRACT

Disclosed embodiments may include an apparatus including a first device layer including first switches, a second device layer including second switches, and a third device layer disposed between the first device layer and the second device layer. The third device layer includes first capacitors. The first switches and the second switches are interconnected with the first capacitors to form a switched capacitor circuit. The switched capacitor circuit is configured to transition between at least two states in response to switching of the first switches and the second switches.

### CROSS-REFERENCE TO RELATED APPLICATIONS

This application is a continuation of International Patent Application No. PCT/US2023/066886 filed May 11, 2023 and entitled “APPARATUS AND METHODS OF FABRICATING A SWITCHED CAPACITOR CIRCUIT,” which claims priority to and the benefits of U.S. Provisional Patent Application No. 63/364,569, filed on May 12, 2022, and U.S. Provisional Patent Application No. 63/364,674, filed on May 13, 2022, the entire contents of which are incorporated herein by reference for all purposes.

### TECHNICAL FIELD

The present disclosure generally relates to power electronic devices. More particularly, the present disclosure relates to power converters.

### BACKGROUND

Modern-day central processing units (CPUs) evolve to deliver greater computing performance, such as artificial intelligence (AI) processing and cloud-computing applications, which leads to an escalation in power demand from a power supply. As a result, power converters in the power supply may occupy a considerable space to meet the increasing current requirements of the CPUs. Accordingly, designing a compact and high-density power converter to reduce the required circuit area, while meeting increased current and space requirements has become a challenge in the field.

### SUMMARY

Embodiments of the present disclosure provide an apparatus. The apparatus includes a first device layer including first switches, a second device layer including second switches, and a third device layer disposed between the first device layer and the second device layer. The third device layer includes first capacitors. The first switches and the second switches are interconnected with the first capacitors to form a switched capacitor circuit. The switched capacitor circuit is configured to transition between at least two states in response to switching of the first switches and the second switches.

Embodiments of the present disclosure provide an apparatus. The apparatus includes cells and a phase device cell. Each of the cells includes a capacitor and a first switch. The phase device cell includes second switches. The cells are stacked vertically over the phase device cell. The capacitor and the first switch in each cell are interconnected with the second switches to form a switched capacitor circuit. The switched capacitor circuit is configured to transition between at least two states in response to switching of the first switch in each cell and the second switches.

Embodiments of the present disclosure provide a method of fabricating a switched capacitor circuit. The method includes: providing a first device layer; disposing a third device layer on the first device layer; interconnecting first capacitors within the third device layer with first switches within the first device layer; disposing a second device layer on the third device layer; and interconnecting second switches within the second device layer with the first capacitors.

Embodiments of the present disclosure provide a method of fabricating a switched capacitor circuit. The method includes: providing a phase device cell including phase switches of a switched capacitor circuit; and stacking cells vertically over the phase device cell, each of the cells including a capacitor and a stack switch. The capacitor and the stack switch in each of the cells are interconnected with the phase switches.

Additional features and advantages of the disclosed embodiments will be set forth in part in the following description, and in part will be apparent from the description, or may be learned by practice of the embodiments. The features and advantages of the disclosed embodiments may be realized and attained by the elements and combinations set forth in the claims.

### BRIEF DESCRIPTION OF THE DRAWINGS

Embodiments and various aspects of the present disclosure are illustrated in the following detailed description and the accompanying figures. It is noted that, in accordance with standard practice in the industry, various features are not drawn to scale. In fact, the dimensions of the various features may be arbitrarily increased or reduced for clarity of discussion.

FIG. 1 is a diagram illustrating an exemplary power converter, in accordance with some embodiments of the present disclosure.

FIGS. 2A-2B are diagram illustrating exemplary switched capacitor circuits, in accordance with some embodiments of the present disclosure.

FIGS. 3A-3D are diagrams illustrating exemplary structures, in accordance with some embodiments of the present disclosure.

FIGS. 4A-4C are diagrams illustrating exemplary passive device layers, in accordance with some embodiments of the present disclosure.

FIG. 4D is a diagram illustrating an exemplary active device layer with the molded interconnect substrate, in accordance with some embodiments of the present disclosure.

FIG. 5 is a diagram illustrating an exemplary switched capacitor circuit, in accordance with some embodiments of the present disclosure.

FIG. 6A is a diagram illustrating an exemplary structure, in accordance with some embodiments of the present disclosure.

FIG. 6B is a diagram illustrating an exemplary substructure, in accordance with some embodiments of the present disclosure.

FIG. 7 is a diagram illustrating an exemplary structure, in accordance with some embodiments of the present disclosure.

FIG. 8A and FIG. 8B are diagrams respectively illustrating exemplary cells, in accordance with some embodiments of the present disclosure.

FIG. 9 is a diagram illustrating an exemplary structure of the cell of FIG. 8A, in accordance with some embodiments of the present disclosure.

FIG. 10 is a diagram illustrating another exemplary cell, in accordance with some embodiments of the present disclosure.

FIG. 11A illustrates a cross-section view of an exemplary portion of an LC network, in accordance with some embodiments of the present disclosure.

FIG. 11B illustrates a cross-section view of an exemplary portion of another LC network, in accordance with some embodiments of the present disclosure.

FIG. 12 is a diagram illustrating an exemplary power converter, in accordance with some embodiments of the present disclosure.

FIG. 13 is a diagram illustrating an exemplary power converter package, in accordance with some embodiments of the present disclosure.

FIG. 14 is a flowchart of a method of fabricating a switched capacitor circuit, in accordance with some embodiments of the present disclosure.

FIG. 15 is a flowchart of another method of fabricating a switched capacitor circuit, in accordance with some embodiments of the present disclosure.

### DETAILED DESCRIPTION

The following disclosure provides many different exemplary embodiments, or examples, for implementing different features of the provided subject matter. Specific simplified examples of components and arrangements are described below to explain the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In this document, the term “coupled” may also be termed as “electrically coupled”, and the term “connected” may be termed as “electrically connected”. “Coupled” and “connected” may also be used to indicate that two or more elements cooperate or interact with each other.

Various embodiments of the present disclosure will be described with respect to embodiments in a specific context, namely a charge pump circuit. As used in this disclosure, the term “charge pump” refers to a switched capacitor network configured to convert an input voltage to an output voltage. Examples of such charge pumps include cascade multiplier, Dickson, Ladder, Series-Parallel, Fibonacci, and Doubler switched capacitor networks, all of which may be configured as a multi-phase or a single-phase network.

The concepts in the disclosure may also apply, however, to other types of power converters. Power converters which convert a higher input voltage power source to a lower output voltage level are commonly known as step-down or buck converters, because the converter is “bucking” the input voltage. Power converters which convert a lower input voltage power source to a higher output voltage level are commonly known as step-up or boost converters, because the converter is “boosting” the input voltage. In addition, some power converters, commonly known as “buck-boost converters,” may be configured to convert the input voltage power source to the output voltage with a wide range, in which the output voltage may be either higher than or lower than the input voltage. In various embodiments, a power converter may be bi-directional, being either a step-up or a step-down converter depending on how a power source is connected to the converter. In some embodiments, an AC-DC power converter can be built up from a DC-DC power converter by, for example, first rectifying an AC input voltage to a DC voltage and then applying the DC voltage to a DC-DC power converter.

High-density, integrated switched-capacitor power converters may be desirable in applications including, but not limited to, data centers or portable electronic devices such as tablets, cell phones, or hand-held computers, and IoT (Internet of Things) devices. Particularly, modern high-performance microprocessors may include billions of transistors switching at several gigahertz and/or consuming hundreds of amperes of current at relatively low voltages (e.g., less than 1.0 V in some circumstances). In addition, power consumption characteristics of modern microprocessors are growing with increasing computing performance, leading to challenges with respect to on-board point-of-load (POL)-type converters and/or data center power delivery facilities. High efficiency, high power density and high bandwidth PoL-type converters may be needed to support hundreds of amperes of current (e.g., greater than 50.0 A in some circumstances) being delivered at relatively lower voltages (e.g., less than 1.0 V). Such PoL-type converters may operate with relatively higher voltage conversion ratios (e.g., greater than 10:1) to support current and/or future high-performance microprocessors. Also, the data center industry may be undergoing a transition from a 12 V bus architecture to a 48 V bus due to increasing server power consumption, which may allow for improved overall efficiency and/or lower cost. Delivering power at 48 V, for example, may also leverage existing 48 V telecom power ecosystems. Power converters that may provide a lower voltage output (e.g., less than 1.0 V), regulated at relatively higher bandwidths, while drawing energy from a relatively high, wide-ranging input voltage (e.g., between 40.0 V to 60.0 V) may be advantageous for supporting high-performance microprocessors and/or for supporting telecommunication loads. Size, cost, and/or performance advantages provided via integration make it desirable to design modular and/or miniaturized dc-dc converters that may be relatively easily scaled in size and/or capabilities for a variety of applications having different voltage and/or current needs.

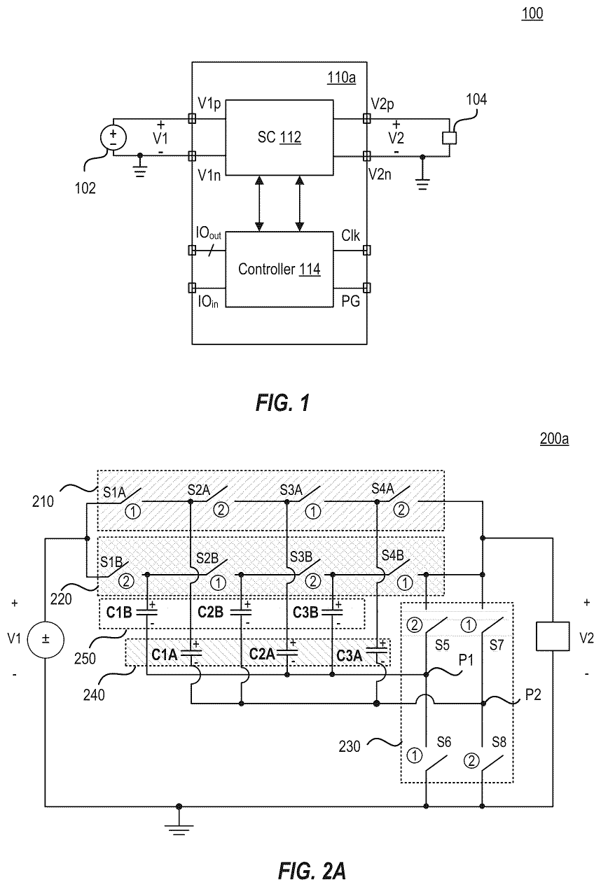

Reference is made to FIG. 1. FIG. 1 is a diagram illustrating an exemplary power converter 100, in accordance with some embodiments of the present disclosure. As shown in FIG. 1, the power converter 100 may include a device 110a, which provides a power module. As used herein, a power module may refer to a physical unit or apparatus containing power and electronic components of a power converter circuit. The device 110a includes a switched capacitor circuit 112 (also known as a charge pump circuit) and a controller circuit 114 configured to control the operation of the switched capacitor circuit 112. Specifically, the controller circuit 114 may include control circuitry, timing circuitry, protection circuitry, and gate drivers, among other components, configured to operate the switches, which in turn may change the electrical configuration of the capacitors of switched capacitor circuit 112 between a first mode/state or second mode/state.

In the embodiments of FIG. 1, the power converter 100 is configured to receive energy from an input voltage source 102 at an input voltage V1 and deliver that energy to an output load 104 at an output voltage V2. In some embodiments, the input voltage V1 may be higher than the output voltage V2. The switched capacitor circuit 112 is configured to convert the input voltage V1 to the output voltage V2. In some embodiments, multiple power modules may be arranged in parallel in the power converter 100 to achieve higher power rating based on low-cost and low-rating devices. Accordingly, the modular design also offers the flexibility and scalability of the power converting circuits to meet different needs in power supply systems in various applications.

In various embodiments, the controller circuit 114 in the device 110a may be an internal master controller or a slave controller configured to communicate with a master controller in the power system. In some other embodiments, the switched capacitor circuit 112 in the device 110a may also be controlled by an external master controller coupled to the device 110a. The controller circuit 114 may be fabricated on a semiconductor substrate such as silicon, gallium nitride (GaN), Silicon-On-Insulator (SOI), Silicon-On-Sapphire (SOS), Silicon-On-Glass (SOG), Silicon-On-Quartz (SOQ), among other substrates, using semiconductor processing techniques compatible with complementary metal oxide semiconductor (CMOS) fabrication. The controller circuit 114 may be physically integrated with the switches in the switched capacitor circuit 112 on the same substrate (e.g., an on-chip configuration) or as an off-chip component configured to operate the switches in the switched capacitor circuit 112.

As shown in FIG. 1, in some embodiments, input terminals V1p, V1n are connected to the input voltage source 102 to receive the input voltage V1, and output terminals V2p, V2n are connected to the output load 104 to output the output voltage V2. In addition, some input terminals of the controller circuit 114, such as a PG terminal for receiving a “Power Good” (PG) signal or a CLK terminal for receiving a clock signal, may be connected to other external circuitry or devices to receive the PG signal and the clock signal. Similarly, I/O pins IOᵢₙ and IOₒᵤₜ of the device 110a may also be connected to corresponding circuitry or devices to facilitate the circuit operations. In the present disclosure, the terms “node” and “terminal” may be used interchangeably.

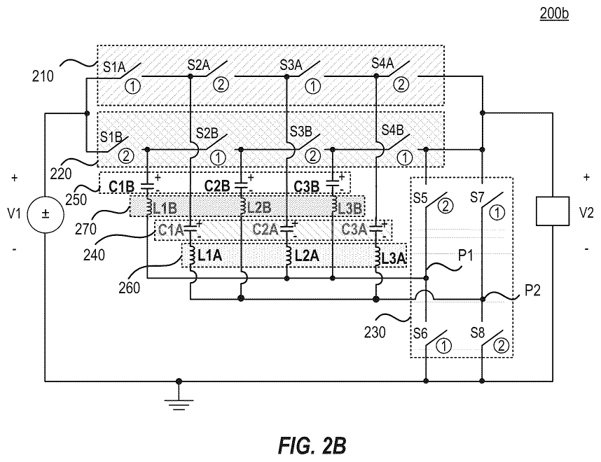

FIG. 2A is a diagram illustrating an exemplary switched capacitor circuit 200a, in accordance with some embodiments of the present disclosure. As shown in FIG. 2A, in some embodiments, the switched capacitor circuit 200a may be a multi-phase switched capacitor circuit, such as a two-phase variant of a Dickson charge pump, also known as a cascade multiplier. In some embodiments, the switched capacitor circuit 200a of FIG. 2A can be used for the switched capacitor circuit 112 in the device 110a of FIG. 1, but the present disclosure is not limited thereto. It is appreciated that, in various embodiments, the switched capacitor circuit may also be single phase or multiple phase circuit, and designed based on a desired conversion ratio. In the embodiments of FIG. 2A, a 4:1 conversion ratio may be obtained. In general, within a Dickson topology, different conversion ratios V1/V2 (e.g., a 3:1 conversion ratio, a 5:1 conversion ratio, etc.) may be obtained by using different numbers of capacitors and different numbers of switches. As the magnitude of the desired conversion ratio increases, the number of capacitors and switches used in a power converter may increase.

In the embodiments of FIG. 2A, the switched capacitor circuit 200a includes stack switches 210 for a first phase, stack switches 220 for a second phase, phase switches 230 shared by both phases, a first set of capacitors 240, including first capacitors C1A, C2A, and C3A, associated with the first phase and connected to the stack switches 210, and a second set of capacitors 250, including second capacitors C1B, C2B, and C3B, associated with the second phase and connected to the stack switches 220. The stack switches 210 associated with the first phase include switches S1A, S2A, S3A, and S4A. The stack switches 220 associated with the second phase include switches S1B, S2B, S3B and S4B. The phase switches 230 include switches S5, S6, S7, and S8. Accordingly, the switched capacitor circuit 200a provides a switching network that causes transitions between first and second states, depending on which of these switches are open and which ones are closed. A first switch configuration causes the switched capacitor network to transition from the first state to the second state. A second switch configuration causes the switched capacitor network to transition from the second state to the first state. As a result of the switches causing the switched capacitor network to switch between these states, the capacitors 240 and 250 are charged or discharged in a charge pump cycle to complete the power conversion and transfer the power from the supply to the load.

In the design shown in FIG. 2A, the switching network includes two switch chains, i.e., switches connected in series. Particularly, stack switches S1A, S2A, S3A, and S4A form one switch chain associated with the first phase, while stack switches S1B, S2B, S3B, and S4B form another switch chain associated with the second phase. Stack switches S1A, S2A, S3A, and S4A are respectively coupled to positive terminals of the first capacitors C1A, C2A, and C3A associated with the first phase via corresponding dc nodes. Similarly, stack switches S1B, S2B, S3B, and S4B are respectively coupled to positive terminals of the second capacitors C1B, C2B, and C3B associated with the second phase via corresponding dc nodes.

Phase switches S5 and S6 are connected to negative terminals of the first and second capacitors C1B, C2A, and C3B via a first phase node P1 while phase switches S7 and S8 are connected to negative terminals of the first and second capacitors C1A, C2B, and C3A via a second phase node P2. In other words, the first phase node P1 is coupled to negative terminals of a first subset of the first capacitors (e.g., capacitor C2A) and a first subset of the second capacitors (e.g., capacitor C1B and C3B), while the second phase node P2 is coupled to negative terminals of a second subset of the first capacitors (e.g., capacitor C1A and C3A) and a second subset of the second capacitors (e.g., capacitor C2B).

During the operation, switches S1A, S2B, S3A, S4B, S6, and S7, which are marked as group 1 in FIG. 2A, and the switches S1B, S2A, S3B, S4A, S5 and S8, which are marked as group 2 in FIG. 2A, may be in complementary states. For example, in a first state, the switches S1A, S2B, S3A, S4B, S6, and S7 may be open and the switches S1B, S2A, S3B, S4A, S5 and S8 may be closed, in response to the commands from the controller circuit. In a second state following the first state, the switches S1A, S2B, S3A, S4B, S6, and S7 may be closed and the switches S1B, S2A, S3B, S4A, S5 and S8 may be open, in response to the commands from the controller circuit. Furthermore, a dead-time interval may exist between the first state and the second state. During the dead-time interval, all the switches are open, which ensures a clean transition between the two switch states. It would be understood that the present disclosure is not limited to such a ratio or type of conversion circuit. In various embodiments, a step-down or a step-up configuration may be applied to all possible charge pump ratios.

FIG. 2B is a diagram illustrating another exemplary switched capacitor circuit 200b, in accordance with some embodiments of the present disclosure. As shown in FIG. 2B, in some embodiments, the switched capacitor circuit 200b may further include a first set of inductors 260, including first inductors L1A, L2A, and L3A, associated with the first phase and respectively connected between corresponding capacitors C1A, C2A, and C3A and the phase switches 230, and a second set of inductors 270, including second inductors L1B, L2B, and L3B, associated with the second phase and respectively connected between corresponding capacitors C1B, C2B, and C3B and the phase switches 230.

As shown in FIG. 2B, various circuit topologies can be used in the present disclosure to form different types of power converters, such as a hybrid converter, a resonant switched capacitor converter, or a multilevel power converter including transistors, capacitors, and one or more inductors as energy storage elements, or a converter with an LC filter coupled with the switched capacitor network to promote adiabatic charging or discharging. Particularly, hybrid converters, such as multi-level power converters or series capacitor buck converters, also include a switched capacitor circuit combined with different topologies.

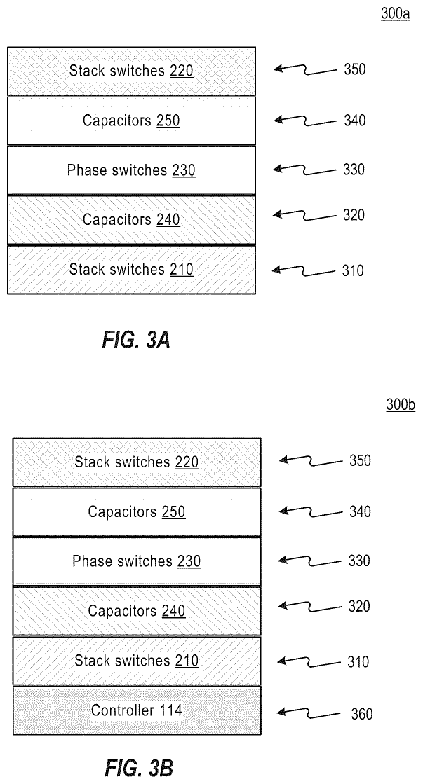

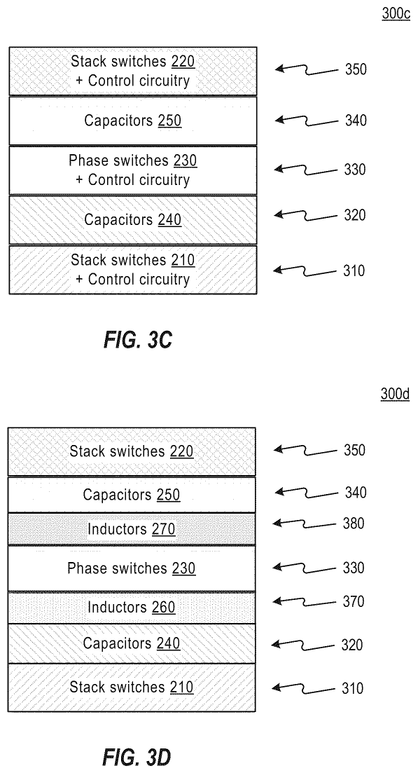

FIG. 3A is a diagram illustrating an exemplary structure 300a, in accordance with some embodiments of the present disclosure. The structure 300a may be used to implement the switched capacitor circuit 200a shown in FIG. 2A. As shown in FIG. 3A, multiple layers 310-350 are stacked vertically, i.e., along a z-direction perpendicular to a substrate, on one another in the structure 300a. Particularly, the structure 300a includes active device layers 310, 330, and 350, and passive device layers 320 and 340. A stacked configuration may include a stack of alternating active device layers 310, 330, and 350 and passive device layers 320 and 340, but the present disclosure is not limited thereto.

In some embodiments, active device layers 310, 330, and 350 may include switching elements (e.g., switches 210, 220, and 230 of FIG. 2A) fabricated on a semiconductor substrate such as, but not limited to, bulk silicon, doped silicon, GaN, GaAs, or SOI. The stack switches 210 and 220, and the phase switches 230 may be implemented by field-effect transistors, bipolar junction transistors, diodes, or other electrical devices. In some embodiments, one or more of the active device layers 310, 330, and 350 may further include control circuitry (e.g., controller circuit 114 of FIG. 1) fabricated on the same semiconductor substrate as the switching elements such that controller circuit 114 is physically integrated with the switches. In some embodiments, passive device layers 320 and 340 may include passive devices including capacitors (e.g., capacitors 240 and 250 of FIG. 2A) or resistors fabricated on a substrate. The substrate may include, but is not limited to, glass, quartz, silicon, SOI, SOS, SOG, SOQ, ceramic (alumina, aluminum-nitride, sapphire), or composite, among other substrate materials.

In the structure 300a, the passive device layer 320 is disposed between the active device layer 310 and the active device layer 330. Specifically, the passive device layer 320 is stacked above the active device layer 310, which may be a bottom layer. The active device layer 330 is stacked above the passive device layer 320. In some embodiments, the active device layer 310 includes first switches (e.g., stack switches 210 in FIG. 2A associated with the first phase). The passive device layer 320 includes first capacitors (e.g., capacitors 240 in FIG. 2A associated with the first phase). The active device layer 330 includes second switches (e.g., phase switches 230 in FIG. 2A shared by the first and the second phases). By providing conductive features (e.g., contacts), the stack switches 210 in the active device layer 310 and the phase switches 230 in the active device layer 330 can be interconnected with the capacitors 240 in the passive device layer 320 to form the switched capacitor circuit for the first phase shown in FIG. 2A. As previously explained in FIG. 2A, the switched capacitor circuit transitions between at least two states in response to switching of the stack switches 210 and the phase switches 230.

Similarly, the passive device layer 340 is disposed between the active device layer 330 and the active device layer 350 to form the switched capacitor circuit for the second phase shown in FIG. 2A. Thus, the phase switches 230 in the active device layer 330 can be shared by two phases and interconnected with both the capacitors 240 and 250. Specifically, the passive device layer 340 is stacked above the active device layer 330, and the active device layer 350, which may be a top layer, is stacked above the passive device layer 340. As used herein, a “bottom” layer is the layer closest to a substrate providing an electrical interface and a “top” layer is the layer furthest from the substrate.

The active device layer 350 includes third switches (e.g., stack switches 220 in FIG. 2A associated with the second phase). The passive device layer 340 includes second capacitors (e.g., capacitors 250 in FIG. 2A associated with the second phase). By providing conductive features (e.g., contacts), the stack switches 220 in the active device layer 350 and the phase switches 230 in the active device layer 330 can be interconnected with the capacitors 250 in the passive device layer 340 to form the switched capacitor circuit for the second phase shown in FIG. 2A.

Accordingly, the structure 300a may form a multi-phase switched capacitor circuit (e.g., the two-phase switched capacitor circuit 200a of FIG. 2A), which transitions between at least two states in response to switching of the stack switches 210, 220 and the phase switches 230 arranged in different active device layers. In the present embodiments, the first switches in a bottom layer (e.g., active device layer 310) may be stack switches 210 associated with the first phase. The third switches in a top layer (e.g., active device layer 350) may be stack switches 220 associated with the second phase. The second switches in an intermediate layer (e.g., active device layer 330) are phase switches 230 for both the first phase and the second phase, to connect the first capacitors in one layer (e.g., passive device layer 320) stacked below the intermediate layer and the second capacitors in another layer (e.g., passive device layer 340) stacked above the intermediate layer to the shared phase nodes (e.g. phase nodes P1 and P2 in FIG. 2A) of the switched capacitor circuit.

It is also noted that in other embodiments, the structure 300a may have multiple passive device layers stacked on a single active device layer, or multiple active device layers stacked on a single passive device layer, or a stack including at least one of a passive device layer, an interconnect layer, and an active device layer. For example, the structure 300a may additionally include an interconnect layer to provide an electrical connection between active device layers and passive device layers, or to provide an electrical connection between devices in active device layers through metal lines.

FIG. 3B is a diagram illustrating another exemplary structure 300b, in accordance with some embodiments of the present disclosure. Compared to the embodiments of FIG. 3A, as shown in FIG. 3B, a controller layer 360 including circuitry of the controller circuit 114 may be disposed as a bottom layer, and the device layers 310-350 are stacked above the controller layer 360. The controller circuit 114 in the controller layer 360 may be coupled with switches in the device layers 310, 330, and 350 through contacts and vias, so as to provide control signals to control the stack switches and the phase switches for each phase. Accordingly, the structure 300b may be used to implement the device 110a shown in FIG. 1.

FIG. 3C is a diagram illustrating another exemplary structure 300c, in accordance with some embodiments of the present disclosure. Compared to the embodiments of FIG. 3A and FIG. 3B, in the structure 300c, the device layers 310, 330, and 350 may respectively include corresponding control circuitry for controlling the switching of the stack switches or the phase switches in the same device layer. In some embodiments, control circuitry in these device layers 310, 330, and 350 may communicate with each other through contacts and vias and collectively perform operations of the controller circuit 114 to provide control signals for each phase. Accordingly, the structure 300c may also be used to implement the device 110a shown in FIG. 1.

FIG. 3D is a diagram illustrating another exemplary structure 300d, in accordance with some embodiments of the present disclosure. Compared to the embodiments of FIG. 3A-FIG. 3C, the structure 300d further includes additional passive device layers 370 and 380. The passive device layers 370 and 380 are inductor layers respectively include inductors 260 and 270 of FIG. 2B. For example, the passive device layer 370 may be stacked between the passive device layer 320 and the active device layer 330, such that inductors (e.g., first inductors L1A, L2A, and L3A in FIG. 2B), in the passive device layer 370 are connected between corresponding capacitors (e.g., first capacitors C1A, C2A, and C3A in FIG. 2B) in the passive device layer 320 and the phase switches 230 in the active device layer 330.

Similarly, the passive device layer 380 may be stacked between the passive device layer 340 and the active device layer 330, such that inductors (e.g., second inductors L1B, L2B, and L3B in FIG. 2B), in the passive device layer 380 are connected between corresponding capacitors (e.g., second capacitors C1B, C2B, and C3B in FIG. 2B) in the passive device layer 340 and the phase switches 230 in the active device layer 330. Accordingly, the structure 300d may also be used to implement the switched capacitor circuit 200b shown in FIG. 2B. It is noted that in other alternative embodiments, the passive device layer 370 may be stacked between the passive device layer 320 and the active device layer 310, the passive device layer 380 may be stacked between the passive device layer 340 and the active device layer 350. The structure 300d in FIG. 3D is an example and not meant to limit the present disclosure.

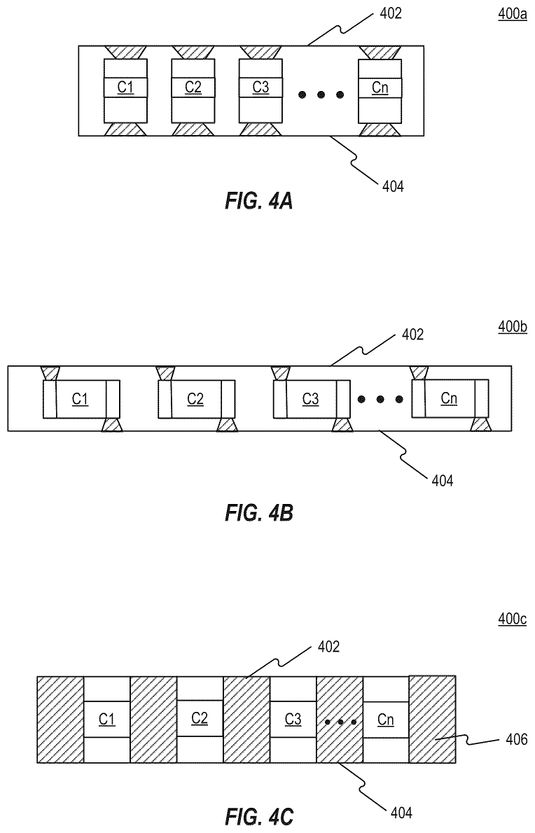

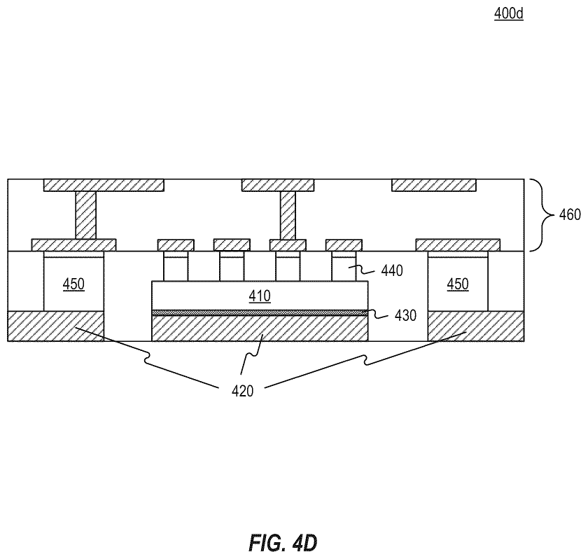

In various embodiments, the passive device layers 320 and 340 may be implemented in different ways to provide vertical capacitors connecting between the phase switches and stack switches, which may reduce the routing distance and reduce the parasitic inductance in the circuit. FIGS. 4A-4C are diagrams illustrating exemplary passive device layers 400a, 400b, and 400c, in accordance with some embodiments of the present disclosure. In some embodiments, the capacitors C1, C2, C3 to Cn embedded in each passive device layer 400a, 400b, or 400c may be multi-layer ceramic capacitors (MLCC). MLCCs may store electric energy in multiple ceramic layers having a high dielectric constant. For example, barium titanate (BaTi03) may be selected as the dielectric. In the structure of a MLCC, numerous metal electrodes and ceramic layers are alternately stacked within the capacitor. The internal electrodes are arranged in an interdigitated pattern with the adjacent electrodes extending to the opposing terminals, while the non-adjacent electrodes extend to the same terminal. On each terminal, a metalized coating applied to the exterior faces, called end termination, electrically connects the exposed electrode edges. MLCCs offer high capacitance, small size, low cost, high reliability, and excellent high-frequency characteristics and can be widely used in different applications.

As shown in FIG. 4A, in some embodiments, positive terminals of the capacitors C1, C2, C3 to Cn are coupled to corresponding contacts located on a first surface 402 of the passive device layer 400a, and negative terminals of the capacitors C1, C2, C3 to Cn are coupled to corresponding contacts located on a second surface 404 of the passive device layer 400a opposite the first surface 402. The passive device layer 400a is stacked with the layer having stack switches via the first surface 402, and stacked with the layer having phase switches via the second surface 404. Thus, the stack switches can be coupled to positive terminals of the capacitors C1, C2, C3 to Cn via dc nodes, and the phase switches can be coupled to negative terminals of the capacitors C1, C2, C3 to Cn via corresponding phase nodes. It would be appreciated that, in different arrangements, the stack switches can be stacked under or over the passive device layer 400a, so the first surface 402 may be either the top surface or the bottom surface. In the embodiments of FIG. 4A, the multi-layer ceramic capacitors C1, C2, C3 to Cn are embedded in the substrate, with the long edge of each multi-layer ceramic capacitor C1, C2, C3 to Cn being substantially perpendicular to the top surface or the bottom surface of the passive device layer 400a, but the present disclosure is not limited thereto.

As shown in the passive device layer 400b in FIG. 4B, the multi-layer ceramic capacitors C1, C2, C3 to Cn may also be embedded in the substrate with the long edge of each multi-layer ceramic capacitor C1, C2, C3 to Cn being substantially parallel to the top surface or the bottom surface of the passive device layer 400b. Similar to the embodiments of FIG. 4A, positive terminals of the capacitors C1, C2, C3 to Cn are coupled to corresponding contacts located on the first surface 402, while negative terminals of the capacitors C1, C2, C3 to Cn are coupled to corresponding contacts located on the second surface 404 opposite the first surface 402. As shown in the passive device layer 400c in FIG. 4C, in some other embodiments, the multi-layer ceramic capacitors C1, C2, C3 to Cn may also be embedded vertically in molded compound material 406, such as a molded plastic or other electrical insulator material, to form the passive device layer 400c. It would be understood that the passive device layer may be realized by other approaches, and the embodiments illustrated in FIGS. 4A-4C are merely examples and not meant to limit the present disclosure.

In some embodiments, the active device layers 310, 330 and 350 and/or the passive device layers 320 and 340 in the structure 300a of FIG. 3A may also be formed using a molded interconnect substrate (MIS), and one or more of the stack switches 210, 220, the phase switches 230, and the capacitors 240, 250 may be embedded with the molded interconnect substrate (MIS). Molded interconnect substrate is a packaging technology built on a lead frame substrate, which supports single-die or multi-die configurations.

FIG. 4D is a diagram illustrating an exemplary active device layer 400d with the molded interconnect substrate, in accordance with some embodiments of the present disclosure. In the active device layer 400d, one or more IC dies 410 including active components (e.g., switches) is attached to a lead frame 420, with a thermal interface material 430 disposed between the IC dies 410 and the lead frame 420. Conductive pillars (e.g., Cu pillars) 440 and 450 are disposed to connect the IC die(s) 410 or the lead frame 420 to an MIS 460 with a pre-molded structure. The MIS 460 may include one or more layers pre-configured with copper plating or interconnects to provide electrical connections.

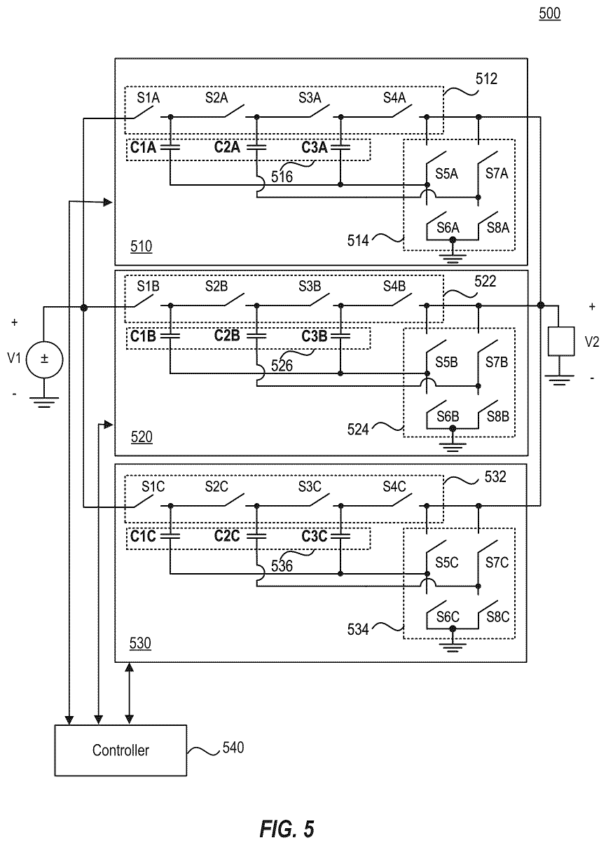

FIG. 5 is a diagram illustrating an exemplary switched capacitor circuit 500, in accordance with some embodiments of the present disclosure. As shown in FIG. 5, in some embodiments, the switched capacitor circuit 500 include multiple single-phase switched capacitor networks 510, 520, and 530 connected in parallel for three different phases. For example, as shown in FIG. 5, the switched capacitor network 510 may be implemented by a 4:1 Dickson switched capacitor network having switches S1A-S8A and capacitors C1A, C2A, and C3A. Similarly, the switched capacitor networks 520 and 530 may be implemented by 4:1 Dickson switched capacitor networks having respective switches S1B-S8B, S1C-S8C and capacitors C1B-C3B, C1C-C3C. The switches S1A-S8A, S1B-S8B, and S1C-S8C may be controlled in response to commands from a controller circuit 540 coupled with the switched capacitor networks 510, 520, and 530.

The switched capacitor network 510 includes stack switches 512 and phase switches 514 for a first phase, and capacitors 516 associated with the first phase. The stack switches 512 associated with the first phase include switches S1A, S2A, S3A, and S4A forming a switch chain. The phase switches 514 include switches S5A, S6A, S7A, and S8A. In the design shown in FIG. 5, stack switches S1A, S2A, S3A, and S4A are respectively coupled to positive terminals of the capacitors C1A, C2A, and C3A via corresponding dc nodes. Phase switches S5A and S6A are connected to negative terminals of the capacitors C1A and C3A via one phase node while phase switches S7A and S8A are connected to the negative terminal of the capacitor C2A via another phase node. Similarly, the switched capacitor networks 520 and 530 respectively include stack switches 522, 532 and phase switches 524, 534 for the second phase or the third phase, and capacitors 526, 536 associated with the second phase or the third phase. Arrangements of circuit components in the switched capacitor networks 520 and 530 are similar to those in the switched capacitor network 510, and thus further details are omitted for the sake of brevity. Compared to the embodiments of FIG. 2A, in the switched capacitor circuit 500, switched capacitor networks 510, 520, and 530 do not shared the phase nodes and phase switches. Capacitors 516, 526, and 536 are coupled to respective sets of phase switches 514, 524, and 534 for different phases.

Like the embodiments of FIG. 2A, in response to the commands from the controller circuit 540, each of the switched capacitor networks 510, 520, and 530 causes transitions between first and second states, depending on which of these switches are open and which ones are closed. Accordingly, charge pumping action arises because of the switches causing the switched capacitor network to switch between these states. In some embodiments, the controller circuit 540 may output corresponding control signals to have the switched capacitor networks 510, 520, and 530 operate 120 degrees out of phase with one another. The topologies shown in FIG. 5 can be further modified to combine N phases in parallel and to run them 360/N degrees out of phase with one another, N being any integer greater than 1. By such arrangements, the switched capacitor circuit 500 provides reduced output voltage ripples and increased output power handling capability.

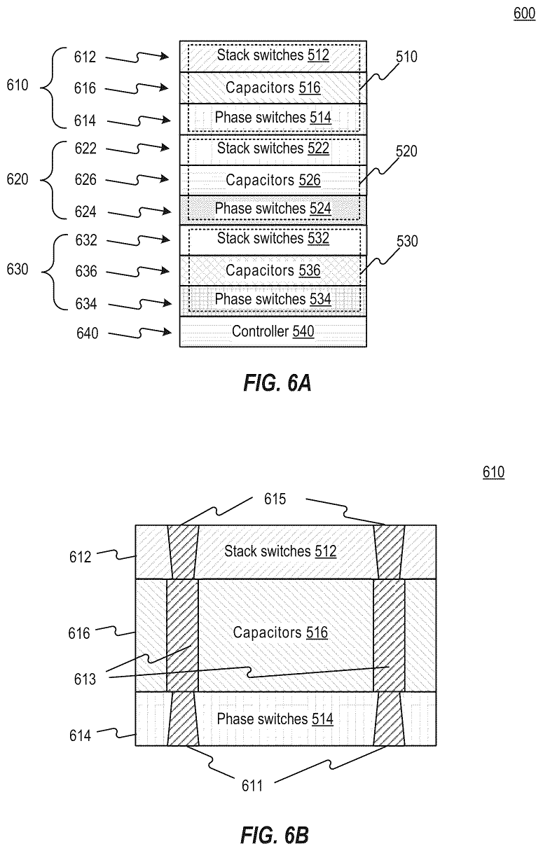

FIG. 6A is a diagram illustrating an exemplary structure 600, in accordance with some embodiments of the present disclosure. The structure 600 may be used to implement the switched capacitor circuit 500 shown in FIG. 5. As shown in FIG. 6A, the structure 600 includes substructures 610, 620, 630, and 640 stacked vertically along the z-direction perpendicular to the substrate on one another.

Each of the substructures 610, 620, and 630 is associated with a corresponding phase of the switched capacitor circuit 500 of FIG. 5. For example, the substructure 610 corresponds to the switched capacitor network 510 for the first phase, the substructure 620 corresponds to the switched capacitor network 520 for the second phase, and the substructure 630 corresponds to the switched capacitor network 530 for the third phase. The substructure 640, which may be a bottom layer under the substructures 610, 620, and 630, includes the controller circuit 540.

As shown in FIG. 6A, each of the substructures 610, 620, and 630 includes the first device layer (e.g., layers 612, 622, or 632) including the stack switches (e.g., stack switches 512, 522, or 524), the second device layer (e.g., layers 614, 624, or 634) including the phase switches (e.g., phase switches 514, 524, or 534), and the third device layer (e.g., layers 616, 626, or 636) including the capacitors (e.g., capacitors 516, 526, or 536) stacked between the first and the second device layers. By providing contacts and vias in each layer of the structure 600, the substructures 610, 620, and 630 can be stacked to one another to couple the switched capacitor networks 510, 520, and 530 in parallel, forming the switched capacitor circuit 500 in FIG. 5. In addition, the controller circuit 540 in the bottom layer may be coupled with switches in the substructures 610, 620, and 630 through these contacts and vias, so as to provide control signals to control the stack switches and the phase switches for each phase.

FIG. 6B is a diagram illustrating an exemplary substructure 610, in accordance with some embodiments of the present disclosure. It would be understood that substructures 620 and 630 may also include the same or similar features of the substructure 610 of FIG. 6B. In FIG. 6B, the passive device layer 616 is stacked above the active device layer 614, and the active device layer 612 is stacked above the passive device layer 616. The substructure 610 provides bottom contacts 611 on a bottom surface and top contacts 615 on a top surface opposite the bottom surface for electrical connections to other substructures stacked above or below the substructure 610. One or more through-vias 613 can be formed and extend elevationally through the active device layer 612, the passive device layer 616, and the active device layer 614. As shown in FIG. 6B, through-vias 613 may be configured to connect corresponding bottom contacts 611 and top contacts 615.

With the stacked structures shown in FIG. 3A or FIG. 6A, a switched capacitor power converter can be formed with its stack switches, capacitors, and phase switches vertically stacked in different layers. Accordingly, the horizontal surface area required for the power converter may be reduced. The structures 300a and 600 disclosed in FIG. 3A and FIG. 6A are suitable for various apparatus or systems, such as power converters used in modern-day datacenters, but the present disclosure is not limited thereto. The disclosed embodiments can also be used in other power applications or scenarios where the package height is less critical.

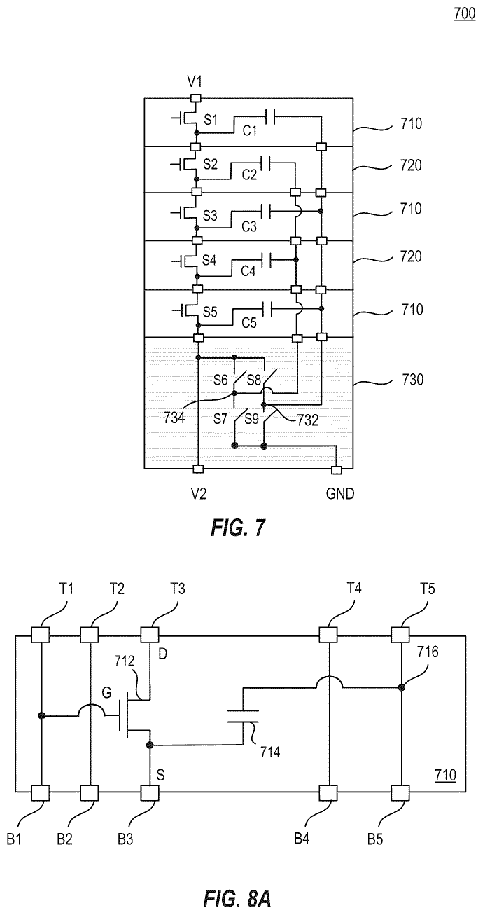

FIG. 7 is a diagram illustrating an exemplary structure 700, in accordance with some embodiments of the present disclosure. The structure 700 may be used to implement a single-phase switched capacitor network. As shown in FIG. 7, the structure 700 includes two sets of cells 710 and 720, and a phase device cell 730. The cells 710 and 720 are stacked vertically on one another and over the phase device cell 730 along the z-direction perpendicular to the substrate. As shown in FIG. 7, each cell 710 or 720 includes top contacts located on a top surface and bottom contacts located on a bottom surface for connecting to contacts of another cell stacked over or below the cell.

Each of the cells 710 and 720 include at least one capacitor (e.g., one of capacitors C1-C5) and a first switch (e.g., one of switches S1-S5) coupled to the positive terminal of the corresponding capacitor. The first switches S1-S5 in the stacked cells 710 and 720 are coupled in series as the stack switches of the single-phase switched capacitor network. The phase device cell 730 includes second switches S6, S7, S8, and S9, which are the phase switches of the single-phase switched capacitor network and coupled to negative terminals of corresponding capacitors C1-C5. By stacking the cells 710 and 720 on the phase device cell 730, the capacitor C1-C5 and the first switch S1-S5 in each cell 710 or 720 are interconnected with the second switches S6, S7, S8, and S9 to form the single-phase switched capacitor network. Like the previous embodiments, the switched capacitor circuit shown in FIG. 7 can be configured to transition between at least two states in response to switching of the first switch S1-S5 in each cell 710 or 720 and the second switches S6-S9.

In the structure 700, cells 710 and 720 are alternatingly stacked so as to couple the capacitors C1-C5 to corresponding phase nodes 732 or 734. Particularly, in each cell 710, the capacitor (e.g., capacitors C1, C3, or C5) is coupled to a first subset of the second switches (e.g., switches S8 and S9) at a first phase node 732 of the switched capacitor circuit, and in each cell 720, the capacitor (e.g., capacitors C2 or C4) is coupled to a second subset of the second switches (e.g., switches S6 and S7) at a second phase node 734 of the switched capacitor circuit.

Like the previous embodiments, in the switch chain including first switches S1-S5, adjacent switches are in complementary states. In other words, during the operation, in a first state, the first switch in each cell 710, e.g., the switches S1, S3, and S5, may be on and the first switch in each cell 720, e.g., the switches S2 and S4, may be off, in response to the commands from the controller circuit. In a second state following the first state, the first switch in each cell 710 may be off and the first switch in each cell 720 may be on, in response to the commands from the controller circuit.

In some embodiments, each of the first switches S1-S5 may be a field-effect transistor having a source terminal and a drain terminal respectively coupled to one of the top contacts and one of the bottom contacts. Each of the capacitor C1-C5 is coupled between the source terminal of the corresponding field-effect transistor and the first phase node 732 or the second phase node 734 of the switched capacitor circuit, through corresponding contacts and/or via in the cells 710 and 720.

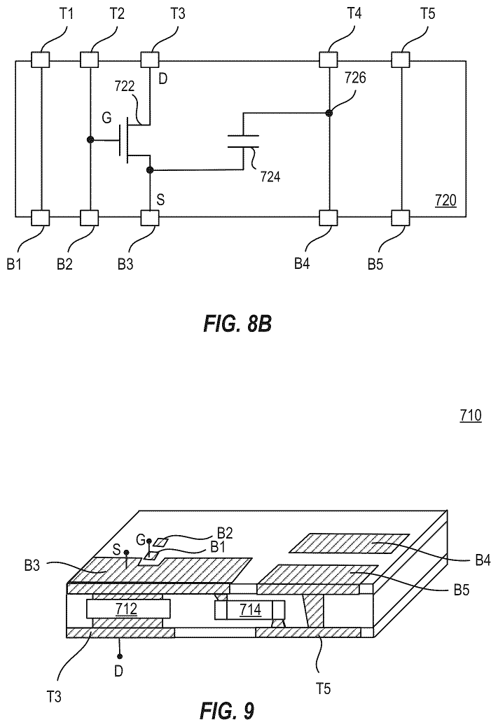

FIG. 8A and FIG. 8B are diagrams respectively illustrating exemplary cells 710 and 720, in accordance with some embodiments of the present disclosure. As shown in FIGS. 8A and 8B, each of the cells 710 and 720 includes top contacts T1-T5 located on a top surface and bottom contacts B1-B5 located on a bottom surface. Top contacts T1, T2, T4 and T5 are respectively coupled to bottom contact B1, B2, B4 and B5 to provide electrical connections among the stacked cells 710 and 720.

In the cells 710 and 720, the source terminal S of the transistor 712 or 722 is coupled to the bottom contact B3, and the drain terminal D of the transistor 712 or 722 is coupled to the top contact T3. For the cell 710 in FIG. 8A, the gate terminal G of the transistor 712 is coupled to the top contact T1 and the bottom contact B1. For the cell 720 in FIG. 8B, the gate terminal G of the transistor 722 is coupled to the top contact T2 and the bottom contact B2. Accordingly, when the cells 710 and 720 are alternatingly stacked, gate terminals of the transistor 712 in the cell 710 are electrically coupled to each other to receive a first control signal, while gate terminals of the transistor 722 in the cell 720 are electrically coupled to each other to receive a second control signal. Thus, adjacent switches in the switch chain may operate in complementary states.

For the cell 710 in FIG. 8A, the capacitor 714 is coupled between the source terminal S of the transistor 712 and a node 716. The node 716 is coupled to the top contact T5 and the bottom contact B5, which will be electrically coupled to a first phase node (e.g., phase node 732 in FIG. 7) of the switched capacitor circuit through the electrical connections among the stacked cells 710 and 720. On the other hand, for the cell 720 in FIG. 8B, the capacitor 724 is coupled between the source terminal S of the transistor 722 and a node 726. The node 726 is coupled to the top contact T4 and the bottom contact B4, which will be electrically coupled to a second phase node (e.g., phase node 734 in FIG. 7) of the switched capacitor circuit through the electrical connections among the stacked cells 710 and 720. Accordingly, when the cells 710 and 720 are alternatingly stacked, the capacitor 714 and the capacitor 724 in adjacent cells are coupled to different subsets of the phase switches, forming the single-phase switched capacitor network shown in FIG. 7.

FIG. 9 is a diagram illustrating an exemplary structure of the cell 710 of FIG. 8A, in accordance with some embodiments of the present disclosure. As shown in FIG. 9, top contacts T1-T5 and bottom contacts B1-B5 may be placed at corresponding locations on opposite surfaces of the cell 710, such that top contacts T1-T5 can be connected to corresponding contacts of adjacent cell 720 stacked over the cell 710, and bottom contacts B1-B5 can be connected to corresponding contacts of adjacent cell 720 stacked under the cell 710. The transistor 712 and the capacitor 714 within the cell 710 may be arranged to optimize electrical connections among the components, the top contacts T1-T5, and bottom contacts B1-B5. A similar structure can be applied to the cell 720 of FIG. 8B, which is not repeated herein for the sake of brevity.

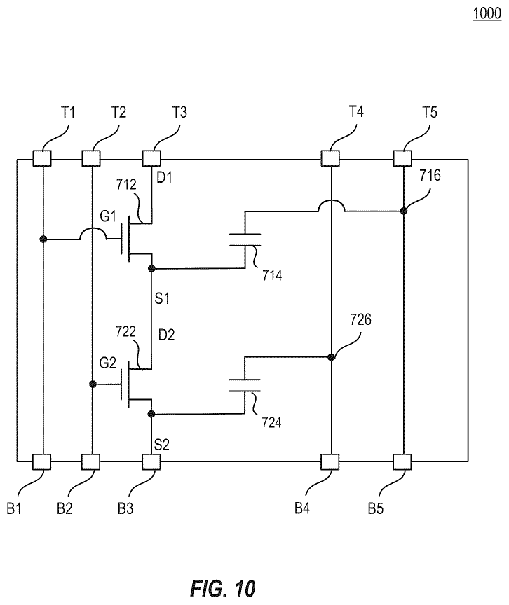

FIG. 10 is a diagram illustrating another exemplary cell 1000, in accordance with some embodiments of the present disclosure. As shown in FIG. 10, the transistors 712 and 722 and the capacitors 714 and 724 operating in complementary states may also be integrated into a single cell to form the switched capacitor network. Accordingly, the single-phase switched capacitor network shown in FIG. 7 may be formed by stacking one or more cells 1000, as an alternative of a pair of one cell 710 and one cell 720. In FIG. 10, the cell 1000 includes the transistors 712 and 722 and the capacitors 714 and 724. Similar to the embodiments of FIG. 8A and FIG. 8B, the capacitor 714 is coupled between the source terminal S1 of the transistor 712 and the node 716 coupling to the top contact T5 and the bottom contact B5, while the capacitor 724 is coupled between the source terminal S2 of the transistor 722 and the node 726 coupling to the top contact T4 and the bottom contact B4.

Transistors 712 and 722 are coupled in series between the top contact T3 and the bottom contact B3. Particularly, the drain terminal D1 of the transistor 712 is coupled to the top contact T3, the drain terminal D2 of the transistor 722 is coupled to the source terminal S1 of the transistor 712, and the source terminal S2 of the transistor 722 is coupled to the bottom contact B3. The gate terminal G1 of the transistor 712 is coupled to the top contact T1 and the bottom contact B1, while the gate terminal G2 of the transistor 722 is coupled to the top contact T2 and the bottom contact B2.

It is noted that while the cell 1000 includes two stack switches (e.g., transistors 712 and 722) and two capacitors 714 and 724 in a single cell, the present disclosure is not limited thereto. In other embodiments, one cell may include any number of stack switches coupled in series and corresponding capacitors coupled to the stack switches. In other words, in some embodiments, at least one of the stacked cells may include multiple capacitors and multiple stack switches that are interconnected with the phase switches to form the switched capacitor circuit.

In the embodiments of FIGS. 7-10, by stacking multiple stackable cells 710, 720 and/or 1000 over the phase device cell 730, a switched capacitor power converter can be formed with its electrical components stacked vertically. Like the embodiments of FIGS. 2A-6D, the horizontal surface area required for the power converter may be reduced, which is desired for various power applications or scenarios where the package height is less critical. In addition, the conversion ratio of the switched capacitor network can be modified easily by stacking different numbers of cells, which offers modularity and flexibility for the power converter design to meet different power requirements in different applications with a low cost.

It would be appreciated that the structures 300a-300d, 600 and 700 in the present disclosure may also be modified and applied to other types of power converters with different implementations, arrangements, and/or topologies. For example, the structures disclosed herein may form a resonant switched capacitor converter or a multilevel power converter including transistors, capacitors, and one or more inductors as energy storage elements, or a converter with an LC filter coupled with the switched capacitor network to promote adiabatic charging or discharging.

In such implementations, capacitors and inductors can be placed in the same passive device layer, or in separate passive device layers. Referring again to FIG. 3A, in some embodiments, the passive device layers 320 or 340 may further include one or more inductors coupled with one or more of the capacitors 240 or 250 in the same layer. Alternatively, as shown in FIG. 3D, the structure 300d may include one or more additional inductor layers, i.e., passive device layers 370 and 380, stacked vertically adjacent to the passive device layers 320 or 340. The passive device layers 370 and 380 include one or more inductors coupled with one or more of the capacitors 240 or 250 in the passive device layers 320 or 340.

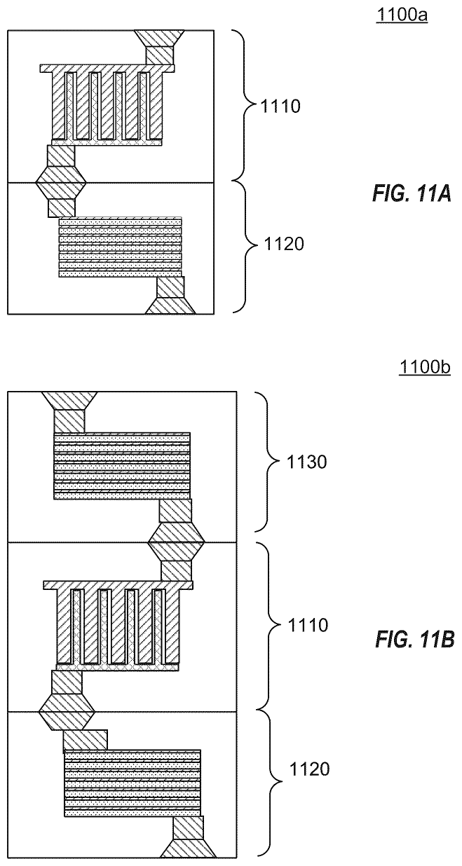

Reference is made to FIG. 11A and FIG. 11B, which illustrate one or more additional inductor layers stacked vertically adjacent to the passive device layer including the capacitors. FIG. 11A illustrates a cross-section view of an exemplary portion of an LC network 1100a, in accordance with some embodiments of the present disclosure. As shown in FIG. 11A, the LC network 1100a may include a capacitor layer 1110 and an inductor layer 1120, with contacts and/or vias configured to enable a series electrical connection of the inductor layer 1120 with the capacitor layer 1110. The LC network 1100a may be fabricated by bonding a bottom surface of the capacitor layer 1110 to a top surface of the inductor layer 1120. In some embodiments, the bonding may include a hybrid bonding such that a metal-to-metal and oxide-to-oxide bond is formed between the bonding surfaces of the capacitor layer 1110 and the inductor layer 1120.

FIG. 11B illustrates a cross-section view of an exemplary portion of another LC network 1100b, in accordance with some embodiments of the present disclosure. In FIG. 11B, the LC network 1100b may include two inductor layers 1120 and 1130, and a capacitor layer 650 coupled between the two inductor layers 1120 and 1130, with contacts and/or vias configured to enable a series electrical connection. As an example, the LC network 1100b may be used in resonant switched capacitor converters. It would be appreciated that the relative arrangement of inductor layers 1120 and 1130 and the capacitor layer 1110 illustrated in FIGS. 11A and 11B are non-limiting examples and other arrangements may be possible as well. In various embodiments, the LC network may include one or more inductor layers, one or more capacitor layers, one or more thru-via, and electrical contact pads, as desired.

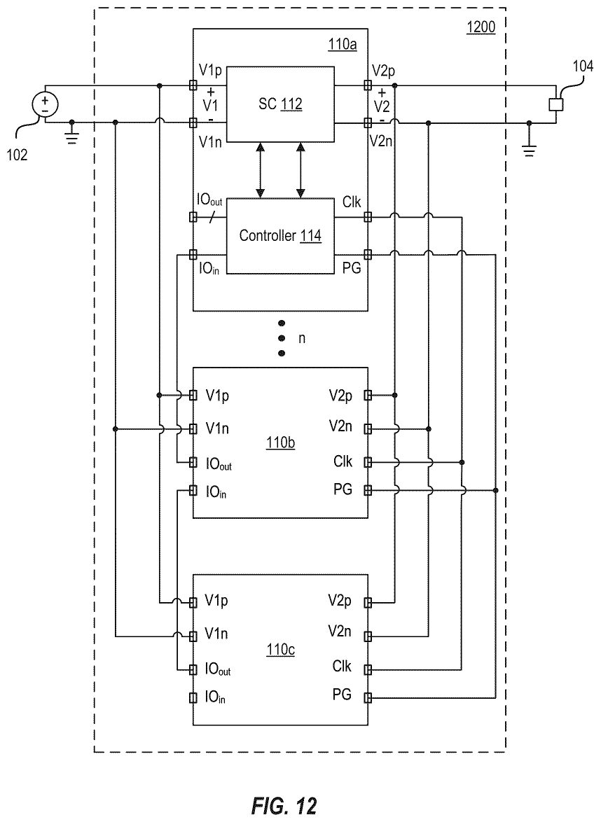

Reference is made to FIG. 12. FIG. 12 is a diagram illustrating an exemplary power converter 1200, in accordance with some embodiments of the present disclosure. Compared to the embodiments of FIG. 1, the power converter 1200 may include multiple devices 110a, 110b, and 110c coupled to each other, and each device provides a power module. In a preferred embodiment, a power module may include one or more of the devices 110a, 110b, and 110c. It is noted that the number of the devices 110a, 110b, and 110c may vary in different embodiments, and FIG. 12 is a simplified example and not meant to limit the present disclosure. In the embodiments of FIG. 12, by using multiple power modules (e.g., including multiple devices 110a, 110b, and 110c) with input terminals V1p and Vin of the switched capacitor circuits connected together and output terminals V2p and V2n of the switched capacitor circuits connected together in the power converter 1200, the power converter 1200 may achieve higher power rating based on low-cost and low-rating devices. Accordingly, the modular design also offers the flexibility and scalability of the power converting circuits to meet different needs in power supply systems in various applications.

In some embodiments, the devices 110a, 110b, and 110c may respectively include corresponding switched capacitor circuit 112 and individual controller circuit 114, but the present disclosure is not limited thereto. In some embodiments, switched capacitor circuits 112 in the devices 110a, 110b, and 110c may be controlled by an external master controller coupled to the devices 110a, 110b, and 110c. In some other embodiments, the power converter 1200 may include one internal master controller (e.g., controller circuit 114 in the device 110a), and one or more slave controllers (e.g., controller circuit 114 in the devices 110b and 110c) configured to communicate with the internal master controller. In addition, one or more of the power modules in the power converter 100 may support Power Management Bus (PMBUS) Communications protocol, while remaining power modules are “light” power modules having a simpler design without PMBUS and/or telemetry circuits.

As shown in FIG. 12, in some embodiments, input terminals V1p, Vin and output terminals V2p, V2n of the switched capacitor circuit 112 in each devices 110a, 110b, and 110c are coupled in parallel. In addition, some input terminals of the controller circuit 114, such as the PG terminal or the CLK terminal, may also be coupled in parallel, such that the devices 110a, 110b, and 110c receive the same PG signal and the same clock signal. Some other terminals, such as I/O pins IOᵢₙ and IOₒᵤₜ of the devices 110a, 110b, and 110c, may be coupled in series to facilitate the circuit operations.

In various embodiments of the present disclosures, for applications where the size of the circuit is critical, the devices 110a, 110b, and 110c including charge pump circuits can be stacked vertically in a package to provide high power density for the power converter 1200. For example, central processing units (CPUs) in laptops or in datacenters may provide sufficient height margins (e.g., approximately 2-9 mm, or approximately 7-22 mm), allowing low profile charge pump power modules to be stacked vertically in a z-direction. Thus, with increased package height, the area occupied by the charge pump circuit on the horizontal surface (i.e., the xy-plane) can be reduced, and the footprint is also saved accordingly.

Compared to the charge pump power module in the present embodiments, a buck converter power module typically has a relatively high-profile inductor, such as a wire-wound inductor. Particularly, the inductor is usually the largest and tallest component in the traditional module, and the bottleneck of reducing the module height in the z-direction. Traditional buck converters would not be stacked due to the height of the large inductor, and such vertically-stacked buck converter power modules would exceed the height constraint and thus are undesired for power supply applications for CPUs in laptops or in datacenters. On the other hand, with the switched-capacitor architecture in the present embodiments, low profile (e.g., approximately 1 mm) charge pump power modules are suitable for stacking in various power supply applications.

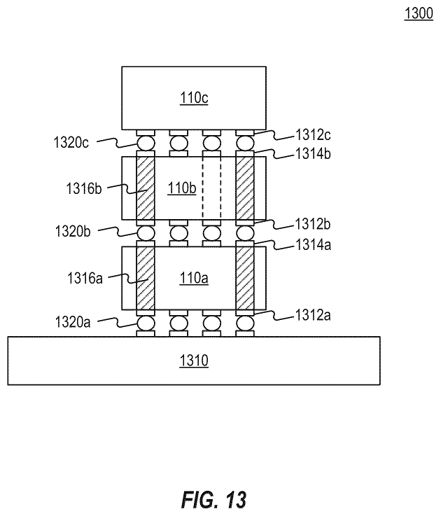

FIG. 13 is a diagram illustrating an exemplary power converter package 1300, in accordance with some embodiments of the present disclosure. The power converter package 1300 includes multiple integrated circuit packages (e.g., devices 110a, 110b, and 110c) stacked vertically to increase the power density, without increasing the overall package area. As shown in FIG. 13, the device 110a at the bottom layer may be a bottom package which provides bottom bonding contacts 1312a on one surface (e.g., a bottom surface), and top bonding contacts 1314a on another surface (e.g., a top surface) opposite the surface having bottom bonding contacts 1312a. One or more through-vias 1316a of the device 110a connect corresponding bottom bonding contact(s) 1312a and corresponding top bonding contact(s) 1314a.

Similarly, the device 110b at an intermediate layer may be an intermediate package which provides bottom bonding contacts 1312b on a bottom surface, and top bonding contacts 1314b on a top surface opposite the bottom surface, with one or more through-vias 1316b connecting corresponding bottom bonding contact(s) 1312b and corresponding top bonding contact(s) 1314b. The device 110c at a top layer may be a top package which provides bottom bonding contacts 1312c on a bottom surface. Alternatively stated, in the embodiments of FIG. 13, bottom bonding contacts on one surface of the package provide connections to a substrate or an adjacent lower package stacked under the package, and top bonding contacts on an opposite surface provide connections to an adjacent upper package stacked over the package.

It is noted that, in some embodiments, the top package may be a stackable package or a non-stackable package. In other words, while the device 110c at the top layer may provide top bonding contacts on the top surface, in some other embodiments, the device 110c may only provide bottom bonding contacts 1312c. It is also noted that, in various embodiments, depending on the application, the orientation of the non-stackable package and stackable package(s) may be varied in the power converter package 1300.

As shown in FIG. 13, the devices 110a, 110b, and 110c are stacked on each other through bondings 1320a, 1320b, and 1320c, which may be electrical bonding (e.g., bumps), thermo-compression bonding, or a hybrid bonding between two adjacent packages. In some embodiments, the bondings 1320a, 1320b, and 1320c may include electrically conductive bumps, which conduct both heat and electrical signals, and thermally-conductive bumps, which are dedicated to heat transfer only. Particularly, bondings 1320a are configured to bond the bottom bonding contacts 1312a in the bottom layer to a substrate, such as a main printed circuit board (PCB) 1310. Bondings 1320b and 1320c are configured to bond the top bonding contacts placed on the top surface of the package in one layer to corresponding bottom bonding contacts placed on the bottom surface of another package in an adjacent layer. The bondings 1320a, 1320b, and 1320c, and through-vias 1316a and 1316b provide electrical connections between the stacked devices 110a, 110b, and 110c. Accordingly, the stacked devices 110a, 110b, and 110c in FIG. 13 can form the power converter 1200 in FIG. 12, in which the switched capacitor circuits in different modules are electrically connected in parallel to each other.

As discussed above, one or more controller circuits configured to control operation of the switched capacitor circuits can be arranged in the devices 110a, 110b, and 110c. In some embodiments, a master controller circuit can be arranged in the bottom package (e.g., device 110a), and slave controller circuit(s) can be arranged in one or more intermediate packages (e.g., device 110b) or in the top package (e.g., device 110c). The slave controller circuit(s) may be electrically connected with the master controller circuit arranged in the bottom package through corresponding bottom bonding contacts 1312a-1312c and top bonding contacts 1314a and 1314b of the integrated circuit packages.

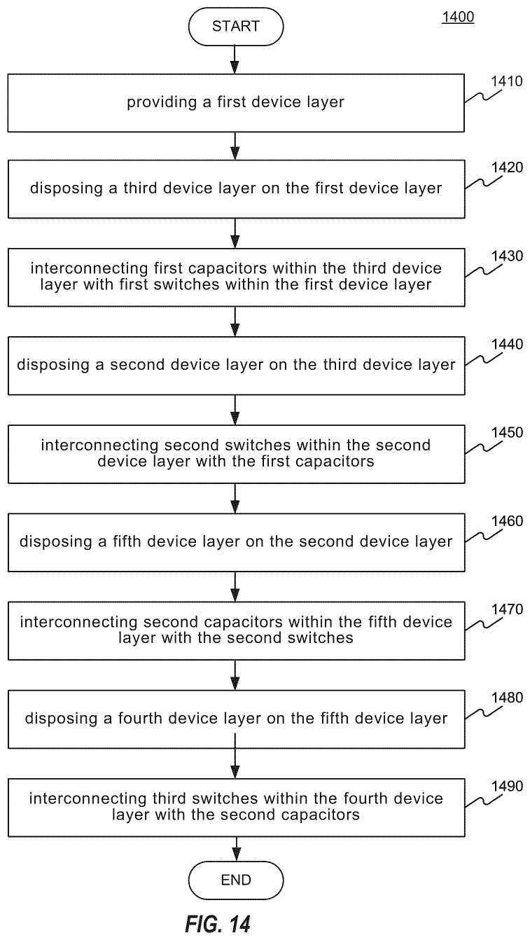

FIG. 14 is a flowchart of a method 1400 of fabricating a switched capacitor circuit, in accordance with some embodiments of the present disclosure. It is understood that additional operations may be performed before, during, and/or after the method 1400 depicted in FIG. 14, and that some other processes may only be briefly described herein. The method 1400 can be performed to fabricate the structure 300a of FIG. 3A for manufacturing integrated circuits for power converter applications, such as the power converter 100 in FIG. 1 and the power converter 1200 of FIG. 12. The method 1400 includes operations 1410-1490.

In the operation 1410, a first device layer (e.g., active device layer 310 in FIG. 3A) is provided. In the operation 1420, a third device layer (e.g., passive device layer 320 in FIG. 3A) is disposed on the first device layer. In the operation 1430, first capacitors (e.g., capacitors 240 in FIG. 3A) within the third device layer are interconnected with first switches (e.g., stack switches 210 in FIG. 3A) within the first device layer. Bottom contacts of the third device layer can be connected with corresponding top contacts of the first device layer to couple positive terminals of the first capacitors to corresponding first switches.

In the operation 1440, a second device layer (e.g., active device layer 330 in FIG. 3A) is disposed on the third device layer. In the operation 1450, second switches (e.g., phase switches 230 in FIG. 3A) within the second device layer are interconnected with the first capacitors. Bottom contacts of the second device layer can be connected with corresponding top contacts of the third device layer to couple negative terminals of the first capacitors to corresponding second switches.

In the operation 1460, a fifth device layer (e.g., passive device layer 340 in FIG. 3A) is disposed on the second device layer. In the operation 1470, second capacitors (e.g., capacitors 250 in FIG. 3A) within the fifth device layer are interconnected with the second switches. Bottom contacts of the fifth device layer can be connected with corresponding top contacts of the second device layer to couple negative terminals of the second capacitors to corresponding second switches.

In the operation 1480, a fourth device layer (e.g., active device layer 350 in FIG. 3A) is disposed on the fifth device layer. In the operation 1490, third switches (e.g., stack switches 220 in FIG. 3A) within the fourth device layer are interconnected with the second capacitors. Bottom contacts of the fourth device layer can be connected with corresponding top contacts of the fifth device layer to couple positive terminals of the second capacitors to corresponding third switches.

Optionally, in some embodiments, in the operation 1420 or 1460, one or more inductor layers (e.g., inductor layers 1120 and/or 1130 in FIG. 11A and FIG. 11B) can be stacked vertically adjacent to the passive device layer (e.g., capacitor layer 1110 in FIG. 11A and FIG. 11B), before or after stacking the third device layer. The inductor layer may include one or more inductors coupled with one or more first capacitors in the passive device layer to form an LC network.

As discussed above, in the method 1400, the first and the fifth device layers can be formed by embedding multi-layer ceramic capacitors vertically in a substrate, with one or more contacts coupled to positive terminals of the multi-layer ceramic capacitors located on a first surface, and one or more contacts coupled to negative terminals of the multi-layer ceramic capacitors located on a second surface opposite the first surface. In some other embodiments, the first and the fifth device layers can be formed by embedding multi-layer ceramic capacitors in the molded compound material. In some other embodiments, one or more of the active device layers or the passive device layers may be formed by embedding the switches and/or the capacitors with a molded interconnect substrate.

By the operations 1410-1490 discussed above, a structure (e.g., structure 300a of FIG. 3A) having multiple layers stacked vertically on one another can be obtained to implement the switched capacitor circuit. A switched capacitor power converter can thus be formed with its stack switches, capacitors, and phase switches vertically stacked in different layers, and the horizontal surface area required for the power converter may be reduced.

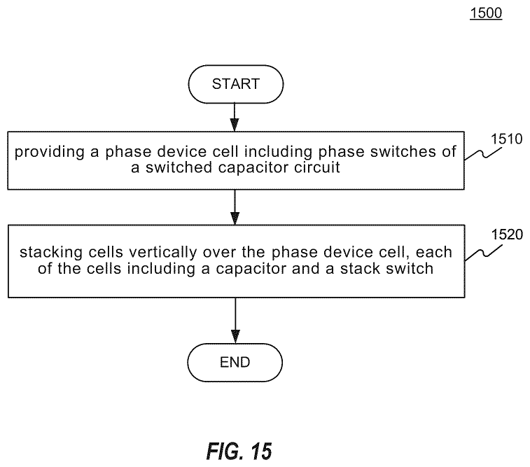

FIG. 15 is a flowchart of another method 1500 of fabricating a switched capacitor circuit, in accordance with some embodiments of the present disclosure. It is understood that additional operations may be performed before, during, and/or after the method 1500 depicted in FIG. 15, and that some other processes may only be briefly described herein. The method 1500 can be performed to fabricate the structure 700 of FIG. 7 for manufacturing integrated circuits for power converter applications, such as the power converter 100 in FIG. 1 and the power converter 1200 of FIG. 12. The method 1500 includes operations 1510 and 1520.

In the operation 1510, a phase device cell (e.g., phase device cell 730 in FIG. 7) including phase switches (e.g., switches S6-S8 in FIG. 7) of a switched capacitor circuit is provided. In the operation 1520, multiple cells (e.g., cells 710 and 720 in FIG. 7) are stacked vertically over the phase device cell. Each of the cells includes a capacitor (e.g., one of capacitors C1-C5) and a stack switch (e.g., one of switches S1-S5). The capacitor and the stack switch in each of the cells are interconnected with the phase switches. In each cell, the capacitor is coupled between corresponding bottom contact and top contact, and the stack switch is coupled between corresponding bottom contact and top contact.

The process of stacking cells in the operation 1520 may include connecting, in each cell, bottom contacts (e.g., bottom contacts B1-B5 in FIG. 8A and FIG. 8B) located on a bottom surface to contacts of another cell stacked below the cell, and connecting, in each cell, top contacts (e.g., top contacts T1-T5 in FIG. 8A and FIG. 8B) located on a top surface to contacts of another cell stacked above the cell.

In some embodiments, in the operation 1520, one or more cells in one set (e.g., cells 710 in FIG. 7) and one or more cells in another set (e.g., cells 720 in FIG. 7) are stacked alternatingly. In each cell 710, the capacitor is coupled to a first subset of the phase switches (e.g., switches S8 and S9 in FIG. 7) at a first phase node (e.g., phase node 732 in FIG. 7) of the switched capacitor circuit. In each cell 720, the capacitor is coupled to a second subset of the phase switches (e.g., switches S6 and S7 in FIG. 7) at a second phase node (e.g., phase node 734 in FIG. 7) of the switched capacitor circuit.

By the operations 1510 and 1520 discussed above, a structure (e.g., structure 700 of FIG. 7) can be obtained to implement the switched capacitor circuit, and a switched capacitor power converter can thus be formed with its electrical components stacked vertically, which reduces the horizontal surface area required for the power converter. As discussed above, by applying the method 1500 to fabricate the switched capacitor circuit, the conversion ratio of the switched capacitor network can be modified easily by stacking different numbers of cells, which offers modularity and flexibility for the power converter design to meet different power requirements in different applications with a low cost.

In summary, in various embodiments of the present disclosure, switches and capacitors can be stacked vertically in different ways to build a single phase or a multiple phase switched capacitor network, which can be applied in various power conversion circuits, such as a charge pump circuit, a resonant switched capacitor converter circuit, a multilevel power converter circuit, etc., to offer an increased power density per unit area. Accordingly, the total area required for the power converter may be reduced, which is desired for data center power delivery facilities and other power applications. It is noted that the switched capacitor circuits and/or power converters in the present disclosure can be realized with a variety of topologies, depending on the desired voltage conversion ratio and permitted switching voltage.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the disclosure disclosed herein. It is also intended that the sequence of steps shown in figures are only for illustrative purposes and are not intended to be limited to any particular sequence of steps. As such, those skilled in the art can appreciate that these steps can be performed in a different order while implementing the same method.

It is appreciated that certain features of the specification, which are, for clarity, described in the context of separate embodiments, may also be provided in combination in a single embodiment. Conversely, various features of the specification, which are, for brevity, described in the context of a single embodiment, may also be provided separately or in any suitable sub-combination or as suitable in any other described embodiments of the specification. Certain features described in the context of various embodiments are not to be considered essential features of those embodiments unless the embodiment is inoperative without those elements.

The embodiments may further be described using the following clauses:

1. An apparatus, comprising:
a first device layer including a plurality of first switches;
a second device layer including a plurality of second switches; and
a third device layer disposed between the first device layer and the second device layer, the third device layer including a plurality of first capacitors,
wherein the plurality of first switches and the plurality of second switches are interconnected with the plurality of first capacitors to form a switched capacitor circuit; and
wherein the switched capacitor circuit is configured to transition between at least two states in response to switching of the plurality of first switches and the plurality of second switches.

2. The apparatus of clause 1, wherein the plurality of first switches are stack switches coupled to positive terminals of the plurality of first capacitors via a plurality of dc nodes; and
wherein the plurality of second switches are phase switches coupled to negative terminals of the plurality of first capacitors via a first phase node or a second phase node.

3. The apparatus of clause 2, wherein the first phase node is coupled to negative terminals of a first subset of the plurality of first capacitors, and the second phase node is coupled to negative terminals of a second subset of the plurality of first capacitors.

4. The apparatus of any of clauses 1-3, further comprising:
a fourth device layer including a plurality of third switches; and
a fifth device layer disposed between the second device layer and the fourth device layer, the fifth device layer including a plurality of second capacitors,
wherein the switched capacitor circuit is a multi-phase switched capacitor circuit;
wherein the plurality of second switches are phase switches for a first phase and a second phase, to connect the plurality of first capacitors and the plurality of second capacitors to shared phase nodes of the switched capacitor circuit;
wherein the plurality of first switches are stack switches associated with the first phase; and
wherein the plurality of third switches are stack switches associated with the second phase.

5. The apparatus of any of clauses 1-4, wherein positive terminals of the plurality of first capacitors are coupled to corresponding contacts located on a first surface of the third device layer, and negative terminals of the plurality of first capacitors are coupled to corresponding contacts located on a second surface of the third device layer opposite the first surface.

6. The apparatus of any of clauses 1-5, wherein the plurality of first capacitors are multi-layer ceramic capacitors.

7. The apparatus of clause 6, wherein the multi-layer ceramic capacitors are embedded in a substrate, a long edge of each multi-layer ceramic capacitor being substantially perpendicular to a top surface of the third device layer.

8. The apparatus of clause 6, wherein the multi-layer ceramic capacitors are embedded in a substrate, a long edge of each multi-layer ceramic capacitor being substantially parallel to a top surface of the third device layer.

9. The apparatus of clause 6, wherein the multi-layer ceramic capacitors are embedded vertically in a molded compound material.

10. The apparatus of any of clauses 1-9, wherein one or more of the plurality of first switches, the plurality of second switches, and the plurality of first capacitors are embedded with a molded interconnect substrate.

11. The apparatus of any of clauses 1-10, wherein the third device layer further includes an inductor coupled with one or more of the plurality of first capacitors to form a resonant switched capacitor converter or a multi-level converter.

12. The apparatus of any of clauses 1-11, further comprising:
an inductor layer stacked vertically adjacent to the third device layer, the inductor layer including an inductor coupled with one or more of the plurality of first capacitors to form a resonant switched capacitor converter or a multi-level converter.

13. The apparatus of any of clauses 1-12, wherein the apparatus comprises a plurality of substructures stacked vertically on one another, each substructure associated with a corresponding phase of the switched capacitor circuit and comprising the first device layer, the second device layer, and the third device layer.

14. The apparatus of clause 13, wherein the plurality of substructures form a multi-phase switched capacitor circuit with n phases being 360/n degrees out of phase with one another, n being any integer greater than 1.

15. An apparatus, comprising:
a plurality of cells, each cell comprising a capacitor and a first switch; and
a phase device cell including a plurality of second switches, the plurality of cells being stacked vertically over the phase device cell,
wherein the capacitor and the first switch in each cell are interconnected with the plurality of second switches to form a switched capacitor circuit; and
wherein the switched capacitor circuit is configured to transition between at least two states in response to switching of the first switch in each cell and the plurality of second switches.

16. The apparatus of clause 15, wherein the plurality of cells comprise two sets of cells alternatingly stacked vertically, wherein in one set of cells, the capacitor is coupled to a first subset of the plurality of second switches at a first phase node of the switched capacitor circuit, and in another set of cells, the capacitor is coupled to a second subset of the plurality of second switches at a second phase node of the switched capacitor circuit.

17. The apparatus of clause 16, wherein during a first state of the switched capacitor circuit, each first switch in the one set of cells is on and each first switch in the another set of cells is off; and
wherein during a second state of the switched capacitor circuit, each first switch in the one set of cells is off and each first switch in the another set of cells is on.

18. The apparatus of any of clauses 15-17, wherein each cell includes:
top contacts located on a top surface of the cell, the top contacts connected to contacts of another cell stacked over the cell; and
bottom contacts located on a bottom surface of the cell, the bottom contact connected to contacts of another cell stacked below the cell.

19. The apparatus of clause 18, wherein a first phase node of the switched capacitor circuit is electrically coupled to one of the top contacts and one of the bottom contacts, and a second phase node of the switched capacitor circuit is electrically coupled to another of the top contacts and another of the bottom contacts.

20. The apparatus of clause 18 or clause 19, wherein each first switch of each cell comprises a field-effect transistor having a source terminal and a drain terminal respectively coupled to one of the top contacts and one of the bottom contacts of the cell.

21. The apparatus of clause 20, wherein in each cell the capacitor is coupled between the source terminal of the field-effect transistor and one of a first phase node or a second phase node of the switched capacitor circuit.

22. The apparatus of any of clauses 15-21, wherein at least one of the cells comprises multiple capacitors and multiple first switches that are interconnected with the plurality of second switches to form the switched capacitor circuit.

23. The apparatus of any of clauses 15-22, wherein at least one of the cells further includes an inductor.

24. A method of fabricating a switched capacitor circuit, comprising:
providing a first device layer;
disposing a third device layer on the first device layer;
interconnecting a plurality of first capacitors within the third device layer with a plurality of first switches within the first device layer;
disposing a second device layer on the third device layer; and
interconnecting a plurality of second switches within the second device layer with the plurality of first capacitors.

25. The method of clause 24, further comprising:
disposing a fifth device layer on the second device layer;
interconnecting a plurality of second capacitors within the fifth device layer with the plurality of second switches;
disposing a fourth device layer on the fifth device layer; and
interconnecting a plurality of third switches within the fourth device layer with the plurality of second capacitors.

26. The method of clause 24 or clause 25, further comprising:
connecting a bottom contact of the third device layer with a corresponding top contact of the first device layer to couple a positive terminal of one of the plurality of first capacitors to one of the plurality of first switches.

27. The method of any of clauses 24-26, further comprising:
connecting a bottom contact of the second device layer with a corresponding top contact of the third device layer to couple a negative terminal of one of the plurality of first capacitors to one of the plurality of second switches.

28. The method of any of clauses 24-27, further comprising:
embedding multi-layer ceramic capacitors vertically in a substrate to form the third device layer;
wherein one or more contacts are coupled to positive terminals of the multi-layer ceramic capacitors located on a first surface of the third device layer; and
wherein one or more contacts are coupled to negative terminals of the multi-layer ceramic capacitors located on a second surface of the third device layer opposite the first surface.

29. The method of any of clauses 24-27, further comprising:
embedding multi-layer ceramic capacitors in a molded compound material to form the third device layer.

30. The method of any of clauses 24-29, further comprising:
embedding one or more of the plurality of first switches, the plurality of second switches, and the plurality of first capacitors with a molded interconnect substrate.

31. The method of any of clauses 24-30, further comprising:
stacking an inductor layer vertically adjacent to the third device layer, the inductor layer including an inductor coupled with one or more of the plurality of first capacitors.

32. A method of fabricating a switched capacitor circuit, comprising:
providing a phase device cell including a plurality of phase switches of a switched capacitor circuit; and
stacking a plurality of cells vertically over the phase device cell, each of the cells including a capacitor and a stack switch;
wherein the capacitor and the stack switch in each of the plurality of cells are interconnected with the plurality of phase switches.

33. The method of clause 32, wherein stacking the plurality of cells comprises:
stacking one or more cells in one set and one or more cells in another set vertically, wherein in each cell in the one set, the capacitor is coupled to a first subset of the plurality of phase switches at a first phase node of the switched capacitor circuit, and in each cell in the another set, the capacitor is coupled to a second subset of the plurality of phase switches at a second phase node of the switched capacitor circuit.

34. The method of clause 32 or clause 33, wherein stacking the plurality of cells comprises:
connecting, in each cell, bottom contacts located on a bottom surface of the cell to contacts of another cell stacked below the cell; and
connecting, in each cell, top contacts located on a top surface of the cell to contacts of another cell stacked above the cell.

35. The method of clause 34, wherein in each cell, the capacitor is coupled between corresponding bottom contact and top contact.

36. The method of clause 34 or clause 35, wherein in each cell, the stack switch is coupled between corresponding bottom contact and top contact.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An apparatus, comprising:
a first device layer including a plurality of first switches;
a second device layer including a plurality of second switches; and
a third device layer disposed between the first device layer and the second device layer, the third device layer including a plurality of first capacitors,
wherein the plurality of first switches and the plurality of second switches are interconnected with the plurality of first capacitors to form a switched capacitor circuit; and
wherein the switched capacitor circuit is configured to transition between at least two states in response to switching of the plurality of first switches and the plurality of second switches.

2. The apparatus of claim 1, wherein the plurality of first switches are stack switches coupled to positive terminals of the plurality of first capacitors via a plurality of dc nodes; and
wherein the plurality of second switches are phase switches coupled to negative terminals of the plurality of first capacitors via a first phase node or a second phase node.

3. The apparatus of claim 2, wherein the first phase node is coupled to negative terminals of a first subset of the plurality of first capacitors, and the second phase node is coupled to negative terminals of a second subset of the plurality of first capacitors.

4. The apparatus of claim 1, further comprising:
a fourth device layer including a plurality of third switches; and
a fifth device layer disposed between the second device layer and the fourth device layer, the fifth device layer including a plurality of second capacitors,
wherein the switched capacitor circuit is a multi-phase switched capacitor circuit;
wherein the plurality of second switches are phase switches for a first phase and a second phase, to connect the plurality of first capacitors and the plurality of second capacitors to shared phase nodes of the switched capacitor circuit;
wherein the plurality of first switches are stack switches associated with the first phase; and
wherein the plurality of third switches are stack switches associated with the second phase.

5. The apparatus of claim 1, wherein positive terminals of the plurality of first capacitors are coupled to corresponding contacts located on a first surface of the third device layer, and negative terminals of the plurality of first capacitors are coupled to corresponding contacts located on a second surface of the third device layer opposite the first surface.

6. The apparatus of claim 5, wherein the plurality of first capacitors are multi-layer ceramic capacitors.

7. The apparatus of claim 6, wherein the multi-layer ceramic capacitors are embedded in a substrate, a long edge of each multi-layer ceramic capacitor being substantially perpendicular to a top surface of the third device layer.

8. The apparatus of claim 6, wherein the multi-layer ceramic capacitors are embedded in a substrate, a long edge of each multi-layer ceramic capacitor being substantially parallel to a top surface of the third device layer.

9. The apparatus of claim 6, wherein the multi-layer ceramic capacitors are embedded vertically in a molded compound material.

10. The apparatus of claim 9, wherein one or more of the plurality of first switches, the plurality of second switches, and the plurality of first capacitors are embedded with a molded interconnect substrate.

11. The apparatus of claim 1, wherein the third device layer further includes an inductor coupled with one or more of the plurality of first capacitors to form a resonant switched capacitor converter or a multi-level converter.

12. The apparatus of claim 1, further comprising:
an inductor layer stacked vertically adjacent to the third device layer, the inductor layer including an inductor coupled with one or more of the plurality of first capacitors to form a resonant switched capacitor converter or a multi-level converter.

13. The apparatus of claim 1, wherein the apparatus comprises a plurality of substructures stacked vertically on one another, each substructure associated with a corresponding phase of the switched capacitor circuit and comprising the first device layer, the second device layer, and the third device layer.

14. The apparatus of claim 13, wherein the plurality of substructures form a multi-phase switched capacitor circuit with n phases being 360/n degrees out of phase with one another, n being any integer greater than 1.

15. An apparatus, comprising:
a plurality of cells, each cell comprising a capacitor and a first switch; and
a phase device cell including a plurality of second switches, the plurality of cells being stacked vertically over the phase device cell,
wherein the capacitor and the first switch in each cell are interconnected with the plurality of second switches to form a switched capacitor circuit; and
wherein the switched capacitor circuit is configured to transition between at least two states in response to switching of the first switch in each cell and the plurality of second switches.

16. The apparatus of claim 15, wherein the plurality of cells comprise two sets of cells alternatingly stacked vertically, wherein in one set of cells, the capacitor is coupled to a first subset of the plurality of second switches at a first phase node of the switched capacitor circuit, and in another set of cells, the capacitor is coupled to a second subset of the plurality of second switches at a second phase node of the switched capacitor circuit.

17. The apparatus of claim 16, wherein during a first state of the switched capacitor circuit, each first switch in the one set of cells is on and each first switch in the another set of cells is off; and
wherein during a second state of the switched capacitor circuit, each first switch in the one set of cells is off and each first switch in the another set of cells is on.

18. The apparatus of claim 15, wherein each cell includes:
top contacts located on a top surface of the cell, the top contacts connected to contacts of another cell stacked over the cell; and
bottom contacts located on a bottom surface of the cell, the bottom contact connected to contacts of another cell stacked below the cell.

19. The apparatus of claim 18, wherein a first phase node of the switched capacitor circuit is electrically coupled to one of the top contacts and one of the bottom contacts, and a second phase node of the switched capacitor circuit is electrically coupled to another of the top contacts and another of the bottom contacts.

20. The apparatus of claim 18, wherein each first switch of each cell comprises a field-effect transistor having a source terminal and a drain terminal respectively coupled to one of the top contacts and one of the bottom contacts of the cell.

21. The apparatus of claim 20, wherein in each cell the capacitor is coupled between the source terminal of the field-effect transistor and one of a first phase node or a second phase node of the switched capacitor circuit.

22. The apparatus of claim 15, wherein at least one of the cells comprises multiple capacitors and multiple first switches that are interconnected with the plurality of second switches to form the switched capacitor circuit.

23. The apparatus of claim 15, wherein at least one of the cells further includes an inductor.
